(19) United States
(12) Patent Application Publication
(10) Pub. No.: US 2026/0239838 A1
(43) Pub. Date: Aug. 13, 2026

(54) DISPLAY APPARATUS

(71) Applicant: LG Display Co., Ltd., Seoul (KR)

(72) Inventors: Jeongmin PARK, Paju-si (KR); Seonghwan WOO, Paju-si (KR)

(21) Appl. No.: 19/435,807

(22) Filed: Dec. 30, 2025

(30) Foreign Application Priority Data
Feb. 7, 2025 (KR) 10-2025-0015767

(51) Int. Cl. H10K 59/131; H10K 59/124; H10K 102/00

(52) U.S. Cl. CPC H10K 59/131; H10K 59/124; H10K 2102/311

(57) ABSTRACT

A display apparatus including a substrate including a display area and a non-display area disposed outside the display area, a link area, a bending area, and a pad area, which are located in the non-display area, a plurality of first signal link wirings disposed in the link area, a plurality of second signal link wirings disposed in the pad area, and a plurality of connection wirings disposed in the bending area, each being electrically connected between one of the plurality of first signal link wirings and one of the plurality of second signal link wirings. The plurality of connection wirings include a first connection wiring and a second connection wiring disposed on different layers with an insulating layer interposed therebetween.

### CROSS REFERENCE TO RELATED APPLICATION

This application claims priority from and the benefit of Korean Patent Application No. 10-2025-0015767, filed on February 7, 2025, which is hereby incorporated by reference for all purposes as if fully set forth herein.

### BACKGROUND

### FIELD

Embodiments of the invention relate generally to a display apparatus.

### DISCUSSION OF THE BACKGROUND

Display apparatuses are applied to various electronic devices, such as TVs, smart phones, laptops, and tablets. To this end, much research has been conducted to develop display apparatuses that are thinner, lighter, and have lower power consumption.

The bezel area of the display apparatus is visually perceived by a user, so that it may become a factor reducing immersion into the image emitted from the display area. Because of this, in recent times, demand has been increasing for display apparatuses that implement a narrow bezel having an enlarged display area and a reduced bezel area where the screen is not displayed, or a zero-bezel having an effect of substantially eliminating the bezel area.

An organic light emitting diode display device (OLED), which is a self-emitting element, may be formed as a thin film. Thus, when a substrate formed from a flexible material is employed, it may be readily folded or bent.

When a flexible substrate of flexible material is applied to the display apparatus, the display panel may include a bending area, a portion of which may be bent to hide a pad area under the display area. In this manner, the bezel area of the display apparatus that can be visually perceived by a user may be reduced.

The bending area includes a plurality of connection wirings for transmitting various signals to pixels on the display area, and the plurality of connection wirings may be electrically connected with signal wirings in a link area adjacent to the display area.

However, when the connection wiring disposed in the bending area is damaged by external impact or the like, it may lead to a problematic situation in which a signal fails to be provided to the display area, causing the display apparatus to have a defect in its operation.

In view of the above, through various experiments, the inventors have conceived of a display apparatus which may continuously operate even if an external force is applied to a local area such as a bending area.

The above information disclosed in this Background section is only for understanding of the background of the inventive concepts, and, therefore, it may contain information that does not constitute prior art.

### SUMMARY

Display apparatuses according to embodiments of the invention are capable of stably providing signals to the display area through connection wirings disposed on the bending area.

Display apparatuses according to embodiments of the invention are capable of providing signals to the display area even when damage occurs to the connection wirings due to an external force applied to a local area such, as the bending area.

Additional features of the inventive concepts will be set forth in the description which follows, and in part will be apparent from the description, or may be learned by practice of the inventive concepts.

According to one or more embodiments of the invention, a display apparatus may include: a substrate including a display area and a non-display area disposed outside the display area; a link area, a bending area, and a pad area, which are located in the non-display area; a plurality of first signal link wirings disposed in the link area; a plurality of second signal link wirings disposed in the pad area; and a plurality of connection wirings disposed in the bending area, each being electrically connected between one of the plurality of first signal link wirings and one of the plurality of second signal link wirings. The plurality of connection wirings may include a first connection wiring and a second connection wiring disposed on different layers, with an insulating layer interposed therebetween.

Each of the first signal link wirings disposed in the link area may overlap with the first connection wiring and the second connection wiring in an up and down direction.

Each of the second signal link wirings disposed in the pad area may overlap with the first connection wiring and the second connection wiring in an up and down direction.

Each of the first connection wiring and the second connection wiring may include at least one deflection point in the bending area, at which the first connection wiring and the second connection wiring are bent in different directions.

The deflection point may include: a first deflection point located in the bending area to be adjacent to the link area; a third deflection point located in the bending area to be adjacent to the pad area; and a second deflection point disposed between the first deflection point and the third deflection point.

The first connection wiring may be disposed in the link area along a first direction, which is a vertical direction of the display area, be disposed at the first deflection point along a second direction different from the first direction, and be disposed at the third deflection point along a third direction different from the second direction. The second deflection point may be in a same direction as the first direction. The second direction may be a diagonal direction toward a lower left. The third direction may include a diagonal direction toward a lower right.

The second connection wiring may be disposed in the link area along a first direction, which is a vertical direction of the display area, be disposed at the first deflection point along a third direction different from the first direction, and be disposed at the third deflection point along a second direction different from the third direction. The second deflection point may be in a same direction as the first direction. The second direction may be a diagonal direction toward a lower left. The third direction may include a diagonal direction toward a lower right.

The plurality of first connection wirings may include first-first connection wirings and first-second connection wirings, which are disposed alternately with each other, and the plurality of second connection wirings may include second-first connection wirings and second-second connection wirings, which are disposed alternately with each other.

The first-first connection wirings and the second-first connection wirings may each be odd-numbered wirings, and the first-second connection wirings and the second-second connection wirings may each include even-numbered wirings.

The first-first connection wirings disposed in a lower side of the insulating layer and the second-second connection wirings disposed in an upper side of the insulating layer may be disposed to overlap with each other in an up and down direction with the insulating layer interposed therebetween.

The first-second connection wirings disposed in a lower side of the insulating layer and the second-first connection wirings disposed in an upper side of the insulating layer may be disposed to overlap with each other in an up and down direction with the insulating layer interposed therebetween.

The second-second connection wirings may include an nth second-second connection wiring among a plurality of second connection wirings, and the first-first connection wirings overlapping with the second-second connection wirings in an up and down direction may include an n+7th first-first connection wiring, which is spaced apart by at least seven lines from the nth second-second connection wiring among a plurality of second connection wirings, where n is a natural number.

The first connection wiring and the second connection wiring may provide a same signal to the display area.

The insulating layer may include an organic insulating layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display panel according to embodiments of the invention.

FIG. 2 is an enlarged view of area II of FIG. 1.

FIG. 3 is a schematic cross-sectional view taken along line I-I' in FIG. 1.

FIG. 4 is a plan view showing an enlarged view of area III of FIG. 2.

FIG. 5 is a cross-sectional view taken along line IV-IV' in FIG. 4.

FIG. 6 is a cross-sectional view taken along line V-V’ in FIG. 4.

FIG. 7 is a cross-sectional view of area III of FIG. 2 showing bending area in a bent position with crack spreading stress.

FIG. 8 is a plan view showing an enlarged view of area III of FIG. 2 according to another embodiment of the invention.

FIG. 9 is a cross-sectional view taken along line VI-VI’ in FIG. 8.

FIG. 10 is a cross-sectional view taken along line VII-VII’ in FIG. 8.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

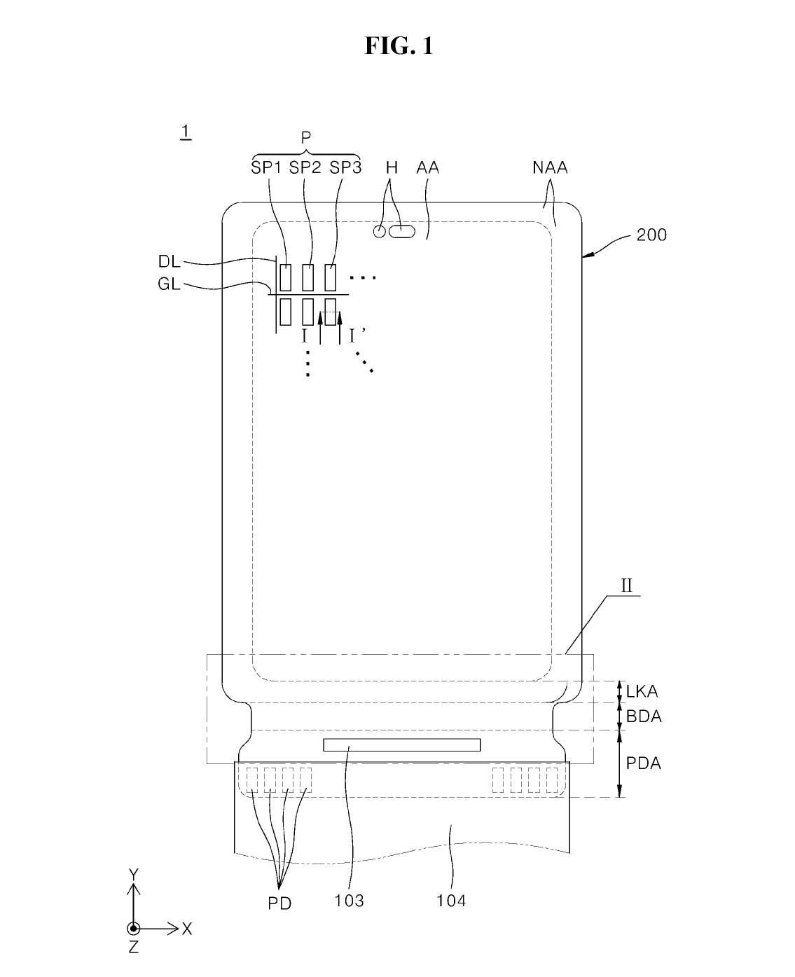

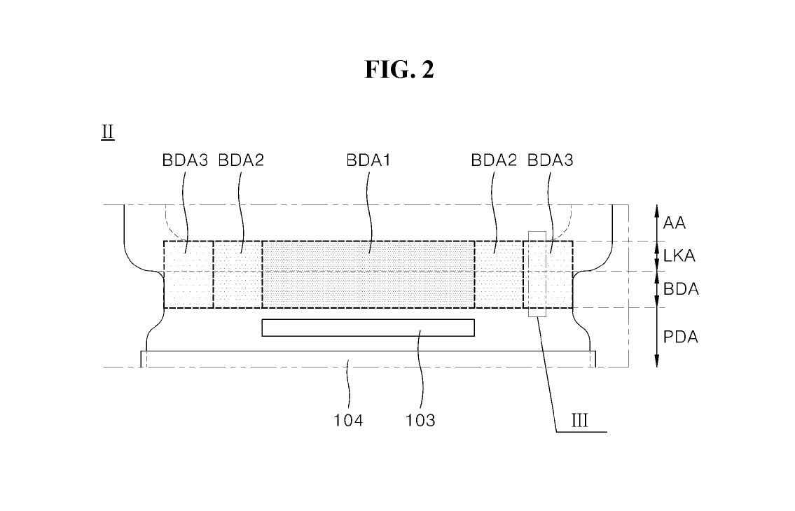

FIG. 1 is a plan view of a display panel according to embodiments of the invention. FIG. 2 is an enlarged view of area II in FIG. 1.

Referring to FIGS. 1 and 2, a display apparatus 1 according to an embodiment of the invention may include a display panel 200, a printed circuit board 104, a driving circuit chip 103, and the like.

The display panel 200 may include a display area AA and a non-display area NAA. The display area AA, which is an area where an image is displayed, may have a plurality of pixels P, data wirings DL, and gate wirings GL disposed therein. The non-display area NAA may be an area where no image is displayed. The non-display area NAA may be located in a peripheral area or border area of the display panel 200, although it is not limited thereto. For example, the remaining area on the display area AA other than a light-emitting area, through which light is emitted to the outside, may be referred to as the non-display area NAA. The non-display area NAA may define a bezel area of the display apparatus. The bezel area may surround the outer side of the display area AA.

In the non-display area NAA, there may be disposed wirings for providing an electrical signal to the display area AA or for receiving an electrical signal from the display area AA. For example, in the non-display area NAA, a gate driving part may be disposed which supplies gate signals to a plurality of subpixels SP1, SP2, SP3 of the display area AA. The gate driving part may be disposed at the right and left edge portions of the non-display area NAA in a GIP (“Gate-In-Panel”) manner. The gate driving part may transmit gate signals through gate lines GL.

The non-display area NAA may include a pad area PDA in which the driving circuit chip 103 and a plurality of pads PD are disposed. The driving circuit chip 103 may transmit data signals to the plurality of sub-pixels SP1, SP2, SP3 through a plurality of data lines DL of the display area AA. For example, the driving circuit chip 103 may be a data driving circuit chip, although it is not limited thereto.

The gate wirings GL may extend in the horizontal direction X of the display panel 200, and the data wirings DL may intersect the gate wirings GL and extend in the vertical direction Y of the display panel 200.

The non-display area NAA may include a link area LKA and a bending area BDA. The link area LKA is disposed between the display area AA and the pad area PDA, and the bending area BDA may be disposed between the link area LKA and the pad area PDA.

The link area LKA may include data link wirings for electrically connecting the plurality of data lines DL of the display area AA with the driving circuit chip 103; gate link wirings for electrically connecting the plurality of gate lines GL with the driving circuit chip 103; or touch link wirings for electrically connecting touch wirings with the driving circuit chip 103.

The data link wirings, touch link wirings, or gate link wirings, which extend from the display area AA to the link area LKA, may extend to the pad area PDA by way of the bending area BDA.

The bending area BDA may include a first bending area BDA1, a second bending area BDA2, and a third bending area BDA3. The first bending area BDA1, the second bending area BDA2, and the third bending area BDA3 may be arranged in the horizontal direction X of the display panel 200, as shown in FIG. 2. The first bending area BDA1 may be an area in which the data lines DL extending from the display area AA by way of the link area LKA are disposed. The second bending area BDA2 may be an area in which the touch wirings extending from the display area AA by way of the link area LKA are disposed. The third bending area BDA3 may be an area in which the gate lines GL extending by way of the link area LKA are disposed. In one example, the second bending area BDA2 and the third bending area BDA3 may be disposed on both sides, respectively, with the first bending area BDA1 interposed therebetween, although it is not limited thereto.

The bending area BDA of the display panel 200 may be bent such that the printed circuit board 104 may be disposed to face the rear surface of the display area AA of the display panel 200. The printed circuit board 104 may include the control circuit chip. The control circuit chip may control the driving circuit chip 103 and the gate driving part.

As the bending area BDA of the display panel 200 is bent, the pad area PDA of the non-display area NAA may be located under the display area AA. Thereby, it is possible to reduce the non-display area in the lower side of the display apparatus 1 perceived from the front of the display apparatus 1.

The display area AA may include a plurality of pixels P and holes H. The hole H may be an area in which an electronic component is disposed for adding various functions to the display apparatus 1. Examples of the electronic component may include a camera module for photographing or recording video in devices such as smartphones, laptops, and tablets, or various sensor devices for sensing an external object. The sensor device may include at least one of a proximity sensor, a gesture sensor, a color sensor, a biometric sensor, and an infrared sensor, although it is not limited thereto.

One pixel P may include a plurality of sub-pixels SP1, SP2, SP3. Through the plurality of sub-pixels SP1, SP2, SP3, an image may be displayed in the display area AA. The plurality of sub-pixels SP1, SP2, SP3 may be disposed in an array on the display area AA. In an example, a plurality of sub-pixels SP1, SP2, SP3 may be disposed to form a matrix type array while being spaced apart from each other in the horizontal direction of the display area AA and the vertical direction intersecting with the first direction. The horizontal direction may be an X-axis direction, a lateral direction, or a row direction, while the vertical direction may be a Y-axis direction, a longitudinal direction, or a column direction. However, this is not exhaustive, and the arrangement shape, arrangement order, and arrangement direction of the sub-pixels SP1, SP2, SP3 may be changed in various ways.

This specification describes an embodiment in which one pixel P is configured with the first sub-pixel SP1, the second sub-pixel SP2, and the third sub-pixel SP3. However, this is not exhaustive. For example, the one pixel P may further include additional sub-pixels.

The sub-pixels SP1, SP2, SP3 may each be implemented to emit light of the same color, such as white light, for every sub-pixel, or may each be implemented to emit light of different colors, such as red, green, or blue light, for every sub-pixel. For example, the first sub-pixel SP1 may implement red; the second sub-pixel SP2 may implement green; and the third sub-pixel SP3 may implement blue.

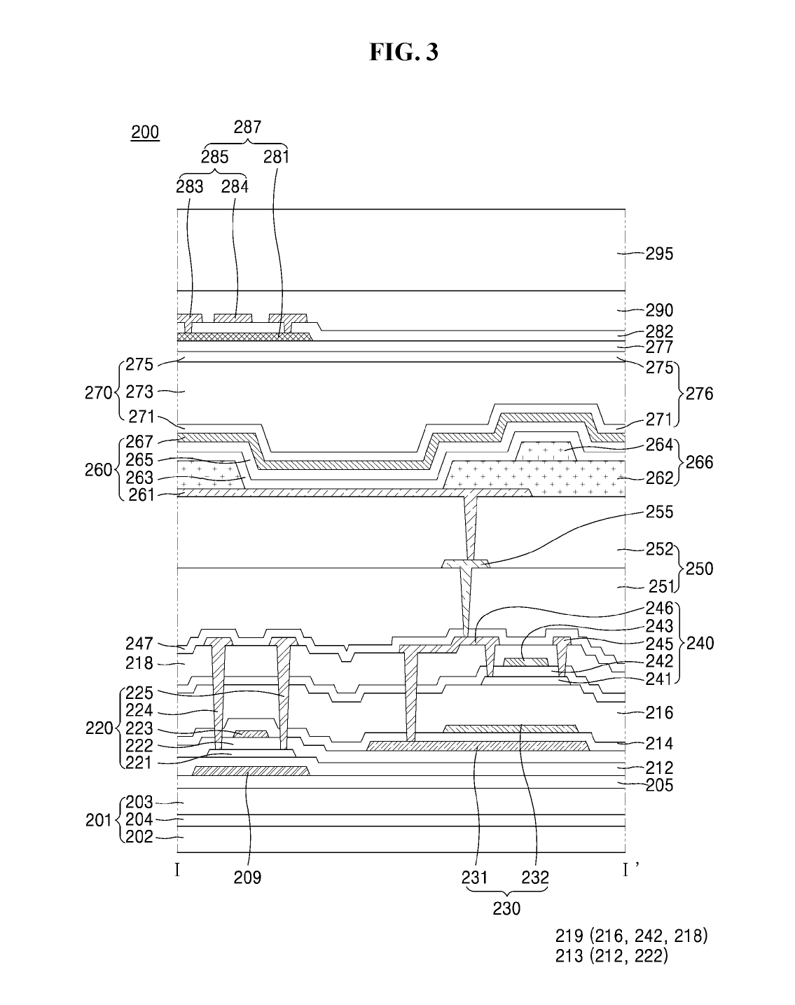

FIG. 3 is a cross-sectional view taken along line I-I' in FIG. 1. FIG. 3 schematically shows one sub-pixel of the display apparatus. For convenience of explanation, the configuration of one sub-pixel will be described, although it is not limited thereto.

Referring to FIG. 3, the display panel 200 may include a pixel driving circuit including a plurality of transistors 220, 240 disposed on a substrate 201, a light-emitting element 260, and a touch sensor part 287.

One sub-pixel may include the light-emitting element 260 and the pixel driving circuit applying a driving current to the light-emitting element 260. The pixel driving circuit is disposed on the substrate 201, and the light-emitting element 260 is disposed on the pixel driving circuit. The pixel driving circuit may include the plurality of transistors 220, 240 and a storage capacitor 230. In one example, the plurality of transistors 220, 240 may include a first transistor 220 and a second transistor 240.

The substrate 201 may be a flexible plastic substrate. In the case where the substrate 201 is a plastic film, it may include multiple layers of insulating material. For example, the substrate 201 may include a first base layer 202, a second base layer 203, and a support layer 204. The first base layer 202 and the second base layer 203 may be disposed in upper and lower positions to be spaced apart from each other, and the support layer 204 may be disposed between them.

The first base layer 202 and the second base layer 203 may include an insulating material having flexibility. For example, the first base layer 202 and the second base layer 203 may include Polyimide (PI). The support layer 204 may support the first and second base layers 202, 203, which have relative flexibility. The support layer 204 may include an insulating material having rigidity relative to the first and second base layers 202, 203. For example, the support layer 204 may include silicon oxide (SiOₓ) or silicon nitride (SiNₓ).

On the substrate 201 a first buffer layer 205 may be disposed. The first buffer layer 205 may cover the surface of the substrate 201. The first buffer layer 205 may reduce or prevent penetration of moisture, oxygen, or impurities through the substrate 201. The first buffer layer 205 may be a single layer or multiple layers made of an inorganic insulating material such as silicon oxide (SiOₓ) or silicon nitride (SiNₓ). The first buffer layer 205 may entirely cover the surface of the substrate 201 in the display area AA. For example, the first buffer layer 205 may extend to the non-display area NAA surrounding the outer side of the display area AA.

On the first buffer layer 205 a light blocking layer 209 may be disposed. The light blocking layer 209 may block external light incident on the transistor. For this purpose, the light blocking layer 209 may include an opaque metal material. On the light blocking layer 209 a second buffer layer 212 may be disposed. The second buffer layer 212 may protect the transistor from moisture, oxygen, or impurities. The second buffer layer 212 may be a single layer or multiple layers made of an inorganic insulating material such as silicon oxide (SiOₓ) or silicon nitride (SiNₓ), although it is not limited thereto. The second buffer layer 212 may entirely cover the surface of the substrate 201 in the display area AA. For example, the second buffer layer 212 may extend to the non-display area NAA surrounding the outer side of the display area AA.

On the second buffer layer 212 the first transistor 220 may be disposed. The first transistor 220 may include a first semiconductor layer 221, a first gate insulating layer 222, a first gate electrode 223, a first source electrode 224, and a first drain electrode 225. In one example, the first transistor 220 may be a switching transistor.

The first semiconductor layer 221 may include a channel area and source/drain areas. An area of the first semiconductor layer 221 overlapping with the first gate electrode 223 in the up and down direction may be the channel area. The source/drain areas may be respectively disposed on both sides of the channel area. The first semiconductor layer 221 may be formed from one or a combination of a polysilicon semiconductor layer and a low-temperature polysilicon semiconductor layer. In another example, the first semiconductor layer 221 may include an oxide semiconductor layer. For example, it may include at least one of oxide semiconductor materials, such as indium gallium zinc oxide (IGZO) or indium zinc oxide (IZO).

When the first semiconductor layer 221 includes an oxide semiconductor layer, the first transistor 220 may be an oxide thin film transistor. The first semiconductor layer 221 may be disposed to overlap with the light blocking layer 209 in the up and downward direction. The light blocking layer 209 may block external light incident on the first semiconductor layer 221.

Between the first semiconductor layer 221 and the first gate electrode 223, the first gate insulating layer 222 may be disposed. The first gate insulating layer 222 may extend outward while covering the first semiconductor layer 221. The first gate insulating layer 222 may be configured in a single layer or a plurality of layers of inorganic insulating material such as silicon oxide (SiOₓ) or silicon nitride (SiNₓ). The first gate insulating layer 222 may entirely cover the surface of the substrate 201 in the display area AA. For example, the first gate insulating layer 222 may extend to the non-display area NAA surrounding the outer side of the display area AA. In the non-display area NAA, the second buffer layer 212 and the first gate insulating layer 222 may be in contact with each other in upper and lower positions to form a first insulating structure 213.

The first gate electrode 223 may be disposed on the first gate insulating layer 222. On the first gate electrode 223 a first interlayer insulating layer 214 may be disposed. The first interlayer insulating layer 214 may be a single layer or multiple layers made of an inorganic insulating material such as silicon oxide (SiOₓ) or silicon nitride (SiNₓ). In one example, the first interlayer insulating layer 214 may extend to the non-display area NAA surrounding the outer side of the display area AA.

The first source electrode 224 and the first drain electrode 225 may be electrically connected to the first semiconductor layer 221.

The storage capacitor 230 may include a first storage electrode 231 and a second storage electrode 232. For example, the first storage electrode 231 may be located in the same layer as the first gate electrode 223. For example, the first storage electrode 231 may be disposed at a different position spaced apart from the first gate electrode 223 on the first gate insulating layer 222. The first storage electrode 231 may be made of the same material as the first gate electrode 223. The second storage electrode 232 may be disposed on the first interlayer insulating layer 214 so as to overlap with the first storage electrode 231 in the up and down direction.

The first storage electrode 231 and the second storage electrode 232 may be a single layer or multiple layers made of any one or an alloy of molybdenum (Mo), aluminum (Al), chromium (Cr), gold (Au), titanium (Ti), nickel (Ni), neodymium (Nd), and copper (Cu). However, it is not limited to these materials.

On the second storage electrode 232 a second interlayer insulating layer 216 may be disposed. The second interlayer insulating layer 216 may be a single layer or multiple layers made of an inorganic insulating material such as silicon oxide (SiOₓ) or silicon nitride (SiNₓ). In one example, the second interlayer insulating layer 216 may extend to the non-display area NAA surrounding the outer side of the display area AA.

On the second interlayer insulating layer 216, the second transistor 240 may be disposed to be spaced apart from the first transistor 220. The second transistor 240 may be electrically connected with the first transistor 220. For example, the second transistor 240 may include a second semiconductor layer 241, a second gate insulating layer 242, a second gate electrode 243, a second source electrode 245, and a second drain electrode 246. In one example, the second transistor 240 may be a driving transistor electrically connected with the light-emitting element 260.

The second semiconductor layer 241 may include a channel area and source/drain areas. The area of the second semiconductor layer 241 which overlaps with the second gate electrode 243 in the up and down direction may be the channel area. The source/drain areas may be respectively disposed on both sides of the channel area. The second semiconductor layer 241 may be configured in an oxide semiconductor layer. For example, it may include at least one of oxide semiconductor materials, such as indium gallium zinc oxide (IGZO) or indium zinc oxide (IZO). In one example, the second semiconductor layer 241 may be disposed so as to overlap with the storage capacitor 230 in the up and down direction. Thereby, the storage capacitor 230 may block external light incident on the second semiconductor layer 241 from the outside of the substrate 201. Therefore, it is possible to prevent the characteristics of the second transistor 240 from being changed by external light.

Between the second semiconductor layer 241 and the second gate electrode 243, the second gate insulating layer 242 may be disposed. The second gate insulating layer 242 may extend outward while covering the second semiconductor layer 241. For example, the second gate insulating layer 242 may extend to the non-display area NAA surrounding the outer side of the display area AA. The second gate insulating layer 242 may be configured in a single layer or a plurality of layers of inorganic insulating material such as silicon oxide (SiOₓ) or silicon nitride (SiNₓ).

The first gate electrode 223 or the second gate electrode 243 may be a single layer or multiple layers made of any one or an alloy of molybdenum (Mo), aluminum (Al), chromium (Cr), gold (Au), titanium (Ti), nickel (Ni), neodymium (Nd), and copper (Cu). However, it is not limited to these materials.

A third interlayer insulating layer 218 may be disposed on the second gate electrode 243. The third interlayer insulating layer 218 may include an insulating material. For example, the third interlayer insulating layer 218 may be a single layer or multiple layers including inorganic insulating materials such as silicon oxide (SiOₓ), silicon nitride (SiNₓ), and silicon oxynitride (SiON). In one example, the third interlayer insulating layer 218 may extend to the non-display area NAA surrounding the outer side of the display area AA. In the non-display area NAA, the second interlayer insulating layer 216, the second gate insulating layer 242, and the third interlayer insulating layer 218 may be in contact with each other in the up-down direction to form a second insulating structure 219.

On the third interlayer insulating layer 218, the first source electrode 224, the first drain electrode 225, the second source electrode 245, and the second drain electrode 246 may be disposed.

The first source electrode 224 and the first drain electrode 225 may penetrate the third interlayer insulating layer 218, the second gate insulating layer 242, the second interlayer insulating layer 216, the first interlayer insulating layer 214, and the first gate insulating layer 222 to be in direct contact with and electrically connected to the source/drain areas of the first semiconductor layer 221, respectively.

The second source electrode 245 and the second drain electrode 246 may penetrate the third interlayer insulating layer 218 and the second gate insulating layer 242 to be in direct contact with and electrically connected to the source/drain areas of the second semiconductor layer 241, respectively. The second drain electrode 246 of the second transistor 240 may be electrically connected with the storage capacitor 230. For example, a portion of the second drain electrode 246 may penetrate the third interlayer insulating layer 218, the second gate insulating layer 242, the second interlayer insulating layer 216, and the first interlayer insulating layer 214 to be in direct contact with and electrically connected to the first storage electrode 231 of the storage capacitor 230.

The first source electrode 224, the first drain electrode 225, the second source electrode 245, or the second drain electrode 246 may be a single layer or multiple layers made of any one or an alloy of molybdenum (Mo), aluminum (Al), chromium (Cr), gold (Au), titanium (Ti), nickel (Ni), neodymium (Nd), and copper (Cu), but is not limited thereto. In one example, the first source electrode 224 or the second drain electrode 246 may be a layer-stacking structure of titanium/aluminum/titanium (Ti/Al/Ti).

On the first source electrode 224, the first drain electrode 225, the second source electrode 245, or the second drain electrode 246, a passivation layer 247 may be disposed. The passivation layer 247 may be a single layer or multiple layers including an inorganic insulating material such as silicon oxide, silicon nitride, and silicon oxynitride. The passivation layer 247 may protect the pixel driving circuit disposed thereunder.

On the passivation layer 247 a planarization layer 250 may be disposed. The planarization layer 250 may planarize a step difference caused by the pixel driving circuit in the lower portion. The planarization layer 250 may include a multilayer structure of a first planarization layer 251 and a second planarization layer 252. For example, the planarization layer 250 may include an organic insulating material, such as polyimide or acrylic resin. In one example, the first planarization layer 251 and the second planarization layer 252 may extend to the non-display area NAA surrounding the outer side of the display area AA.

On the first planarization layer 251 a pixel contact electrode 255 may be disposed. The pixel contact electrode 255 may penetrate the first planarization layer 251 and the passivation layer 247 to be in direct contact with the second drain electrode 246 of the second transistor 240.

On the planarization layer 250, the light-emitting element 260 may be formed. For example, on the second planarization layer 252, the light-emitting element 260 may be disposed. The light-emitting element 260 may include a first electrode 261, a light-emitting layer 263, a second electrode 265, and a capping layer 267.

The light-emitting element 260 may be electrically connected with the pixel driving circuit through the first electrode 261. For example, the first electrode 261 may penetrate the second planarization layer 252 to be in direct contact with the pixel contact electrode 255. Thereby, the first electrode 261 may be electrically connected to the second transistor 240 through the pixel contact electrode 255. However, FIG. 2 is for explaining one example of a method of supplying current to the first electrode 261, and it is not limited to the physical contact with the second transistor 240, which is the driving transistor, and the first electrode 261. In one example, a switching transistor electrically connected to the first electrode 261 may be a light-emitting transistor. For example, the light-emitting transistor may control the turn-on and turn-off states of the light-emitting element 260. The pixel contact electrode 255 may include a conductive material. For example, the pixel contact electrode 255 may include a metallic material such as aluminum (Al), chromium (Cr), copper (Cu), titanium (Ti), molybdenum (Mo), and tungsten (W). In one example, the pixel contact electrode 255 may have a multilayer structure of titanium/aluminum/titanium (Ti/Al/Ti).

The first electrode 261 may include a transparent conductive film. For example, the first electrode 261 may include indium-tin-oxide (ITO) or indium-zinc-oxide (IZO). Alternatively, the first electrode 261 may include a single-layer or multilayer structure including a reflective metal film formed from one or an alloy of silver (Ag), aluminum (Al), gold (Au), nickel (Ni), and chromium (Cr). The first electrode 261 may also be referred to as an “anode electrode” or “pixel electrode”.

On the first electrode 261 a bank 262 may be disposed. The bank 262 may be disposed so as to cover the edges of the first electrode 261. A portion of the bank 262 may extend to the second planarization layer 252. The upper surface of the first electrode 261 that is exposed without being covered by the bank 262 may become a light-emitting area. The bank 262 may be formed from an organic insulating material. The bank 262 may include, for example, photosensitive polyimide, photoacrylic, or benzocyclobutene (BCB).

On the bank 262 a spacer 264 may be further disposed. The spacer 264 may be disposed to prevent damage to the bank 262 and the first electrode 261 during a process procedure. The spacer 264 may be formed from the same material as the bank 262. The bank 262 and the spacer 264 may be stacked in the up and down direction to form an organic insulating structure 266.

On the first electrode 261 a light-emitting layer 263 may be disposed. The light-emitting layer 263 may include a hole transport layer (HTL), an organic light-emitting layer (EML), an electron transport layer (ETL), a hole blocking layer (HBL), a hole injecting layer (HIL), an electron blocking layer (EBL), and an electron injecting layer (EIL). The light-emitting layer 263 may have a multi-stack structure in which two or more organic light-emitting layers (EMLs) are stacked.

On the light-emitting layer 263, the second electrode 265 may be disposed. The second electrode 265 may be commonly connected with the light-emitting layers 263 formed in all pixels. Therefore, the second electrode 265 may also be referred to as a “cathode electrode” or a “common electrode”. The second electrode 265 may include a semi-transparent conductive material. For example, it may be formed from a metal material such as magnesium (Mg), silver (Ag), or an alloy of silver (Ag) and magnesium (Mg) (Ag-Mg). In one example, the second electrode 265 may include a transparent conductive film of indium tin oxide (ITO), indium zinc oxide (IZO), or the like.

On the second electrode 265, the capping layer 267 may be disposed. The capping layer 267 may improve light extraction efficiency by preventing light generated from the light-emitting layer 263 from being lost.

On the light-emitting element 260 an encapsulation part 270 may be disposed. The encapsulation part 270 may protect the light-emitting element 260 from external oxygen or moisture. The encapsulation part 270 may extend to the non-display area NAA outside the display area AA while covering the display area AA.

The encapsulation part 270 may include a multilayer structure in which a first encapsulation layer 271, a second encapsulation layer 273, and a third encapsulation layer 275 are disposed. The second encapsulation layer 273 may be configured to be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271, and may have a sufficient thickness to have a flat surface. The second encapsulation layer 273 may prevent foreign substances from penetrating into the light-emitting element 260. On the second encapsulation layer 273, the third encapsulation layer 275 may be disposed. The first encapsulation layer 271 and the third encapsulation layer 275 may extend to the non-display area NAA surrounding the outer side of the display area AA.

The first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one material selected from silicon nitride (SiNₓ), silicon oxide (SiOₓ), and silicon oxynitride (SiON). The second encapsulation layer 273 may include at least one material selected from epoxy, polyimide, polyethylene, and acrylate.

On the encapsulation part 270 a touch part may be disposed. The touch part may include a touch buffer layer 277, the touch sensor part 287, a touch interlayer insulating layer 282, a first touch protective layer 290, and a second touch protective layer 295.

The touch buffer layer 277 may be disposed on the third encapsulation layer 275. The touch buffer layer 277 may relieve stress between the encapsulation part 270 and the touch sensor part 287 layer to prevent the encapsulation part 270 and the light-emitting element 260 from being damaged. The touch buffer layer 277 may include an inorganic insulating material. For example, the touch buffer layer 277 may include silicon nitride (SiNₓ).

The touch sensor part 287 may include a plurality of touch electrodes 285 and a bridge electrode 281. The plurality of touch electrodes 285 and the bridge electrode 281 may be disposed on different layers. For example, the bridge electrode 281 may be disposed on the touch buffer layer 277. The plurality of touch electrodes 285 may be disposed on the touch interlayer insulating layer 282. The plurality of touch electrodes 285 may include a first touch electrode 283 and a second touch electrode 284. The bridge electrode 281 may electrically connect between adjacent first touch electrodes 283. For this, the first touch electrode 283 may penetrate the touch interlayer insulating layer 282 to be electrically connected to the bridge electrode 281. The touch interlayer insulating layer 282 may include an inorganic insulating material. For example, the touch interlayer insulating layer 282 may include silicon nitride (SiNₓ).

The first touch electrode 283, the second touch electrode 284, or the bridge electrode 281 may include a conductive material. The first touch electrode 283, the second touch electrode 284, or the bridge electrode 281 may include a single layer or multiple layers made of any one or an alloy of molybdenum (Mo), aluminum (Al), chromium (Cr), gold (Au), titanium (Ti), nickel (Ni), neodymium (Nd), and copper (Cu).

The touch buffer layer 277 and the touch interlayer insulating layer 282 may extend toward the non-display area NAA.

On the touch sensor part 287 a first touch protective layer 290 may be disposed. The first touch protective layer 290 may prevent damage to the touch sensor part 287 caused by external impact and moisture. The first touch protective layer 290 may include an organic insulating material. For example, the first touch protective layer 290 may be made of a photosensitive acrylic-based or polyimide-based organic material. The first touch protective layer 290 may extend to the non-display area NAA.

On the first touch protective layer 290, the second touch protective layer 295 may be disposed. The second touch protective layer 295 may further protect the touch sensor part 287 from external impact and moisture. Additionally, the second touch protective layer 295 may planarize a step difference caused by patterns constituting the touch sensor part 287 therebelow. The second touch protective layer 295 may include an organic insulating material. For example, the second touch protective layer 295 may include the same organic insulating material as the first touch protective layer 290, although it is not limited thereto. For example, the second touch protective layer 295 may include an organic insulating material different from that of the first touch protective layer 290.

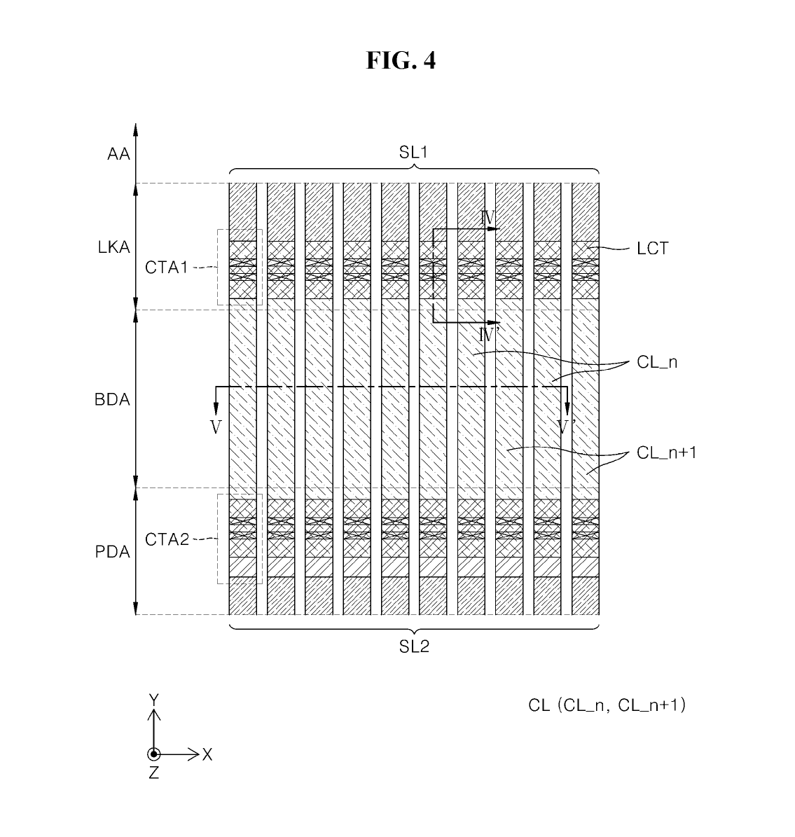

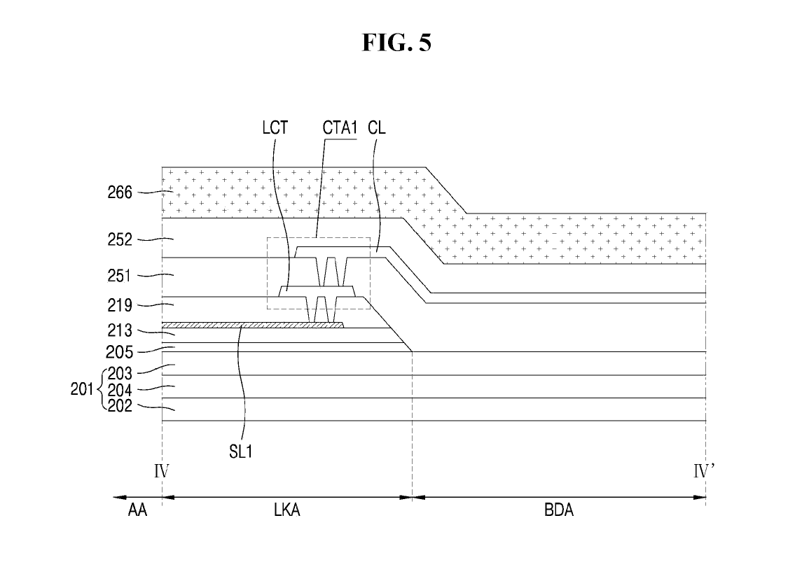

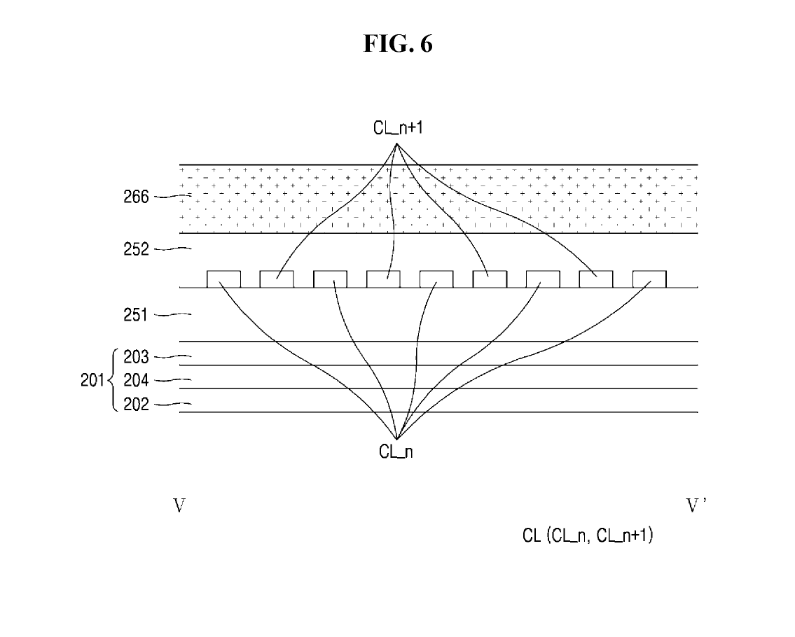

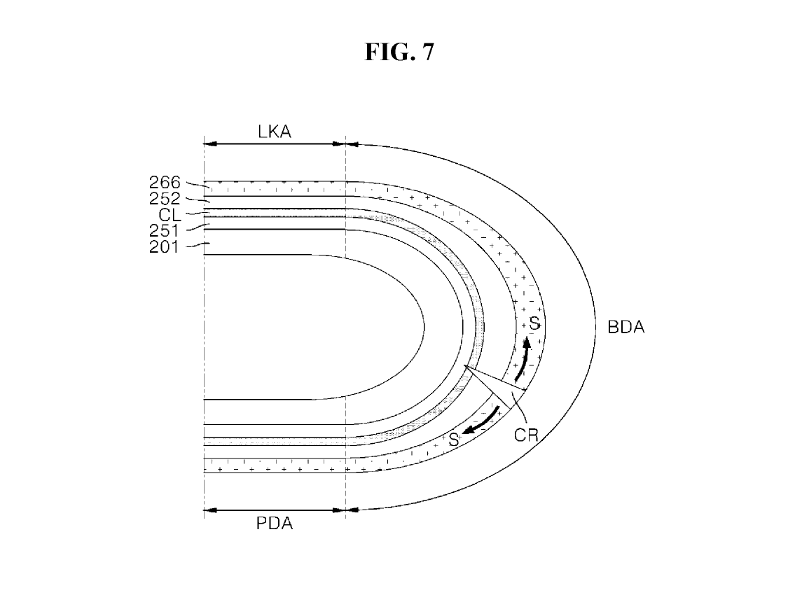

FIGS. 4 to 7 are views according to an embodiment of the invention. FIG. 4 is a plan view showing an enlarged view of area III of FIG. 2. FIG. 5 is a cross-sectional view taken along line IV-IV' in FIG. 4. FIG. 6 is a cross-sectional view taken along line V-V’ in FIG. 4. FIG. 7 is a cross-sectional view taken of area III of FIG. 2 showing bending area BDA in a bent position with crack CR spreading stress S. FIGS. 5 and 6 illustrate the organic insulating structure 266 (having the bank 262 and the spacer 264 shown in FIG. 3) stacked in the up and down direction, for convenience of explanation, while omitting the encapsulation part 270 and the touch sensor part 287, and the like, which are disposed in the upper side of the organic insulating structure 266.

FIG. 4 may show a portion of the link area LKA, the bending area BDA, and the pad area PDA of the display panel 200. For example, FIG. 4 shows a portion of an area in which data link wirings are disposed to transmit signals for driving pixels in the display area AA.

Referring to FIGS. 4 to 6, on the link area LKA, a plurality of first signal link wirings SL1 may be disposed, which transmit signals to the display area AA. For example, the plurality of first signal link wirings SL1 may include a plurality of data link wirings. Each of the plurality of first signal link wirings SL1 may be electrically connected to a second signal link wiring SL2 through a plurality of connection wirings CL.

Each of the plurality of first signal link wirings SL1 may extend in the vertical direction Y in the link area LKA. Adjacent first signal link wirings SL1 may be arranged to be spaced apart from each other in the horizontal direction X. The horizontal direction X may be referred to as the lateral direction of the display panel. The vertical direction Y may be referred to as the longitudinal direction of the display panel.

The plurality of connection wirings CL may extend from the link area LKA to the pad area PDA through the bending area BDA. The connection wiring CL may extend in the vertical direction Y in the bending area BDA. One end portion of each of the plurality of connection wirings CL may overlap with the first contact area CTA1 of the link area LKA, and the other end portion thereof extending to the pad area PDA through the bending area BDA may overlap with the second contact area CTA2 of the pad area PDA. One end portion of the connection wiring CL may be electrically connected with the first signal link wiring SL1 in the first contact area CTA1, and the other end portion thereof may be electrically connected with the second signal link wiring SL2 in the second contact area CTA2.

The plurality of connection wirings CL may include a plurality of odd-numbered wirings CL_n (n is a natural number) and a plurality of even-numbered wirings CL_n+1 (n is a natural number). The plurality of odd-numbered wirings CL_n and the plurality of even-numbered wirings CL_n+1 may be alternately disposed.

Referring to FIGS. 5 and 6, on the link area LKA of the substrate 201, a first buffer layer 205 may be disposed. The substrate 201 may be a multilayer structure including the first base layer 202, the second base layer 203, and the support layer 204. On the first buffer layer 205, the first insulating structure 213 may be disposed. The first insulating structure 213 may be a structure in which the second buffer layer 212 and the first gate insulating layer 222 are in contact with each other in the up and down direction, each including an inorganic insulating material.

On the first insulating structure 213, the first signal link wiring SL1 may be disposed. For example, the first signal link wiring SL1 may be a data link line, although it is not limited thereto. The first signal link wiring SL1 may include the same material as one of the first gate electrode 223, the second gate electrode 243, or the second storage electrode 232. For example, the first signal link wiring SL1 may be a single layer or multiple layers made of any one or an alloy of molybdenum (Mo), aluminum (Al), chromium (Cr), gold (Au), titanium (Ti), nickel (Ni), neodymium (Nd), and copper (Cu). However, it is not limited to these materials.

In the embodiments of the invention, for convenience of explanation, the first signal link wiring SL1 will be described, by way of example, as being formed from the same material as, and in the same process as, the first gate electrode 223. Also, in the embodiments of the invention, for convenience of explanation, the first signal link wiring SL1 will be described, by way of example, as being configured in a single layer, although it is not limited thereto. For example, the first signal link wiring SL1 may be configured in multiple layers disposed in different layers.

On the first signal link wiring SL1, the second insulating structure 219 may be disposed. The second insulating structure 219 may be a structure in which the second interlayer insulating layer 216, the second gate insulating layer 242, and/or the third interlayer insulating layer 218 on the display area AA are in contact with each other in the up and down direction.

On the second insulating structure 219 a link contact electrode LCT may be disposed. The link contact electrode LCT may be formed from the same material as, and in the same process as, the second source electrode 245 and the second drain electrode 246 on the display area AA. The link contact electrode LCT may be electrically connected with the first signal link wiring SL1. For example, the link contact electrode LCT may penetrate the second insulating structure 219 to be electrically connected with the first signal link wiring SL1. The end portion of the link contact electrode LCT may be located further inward than the end portion of the second insulating structure 219.

On the second insulating structure 219 and the link contact electrode LCT, the first planarization layer 251 may be disposed. The first planarization layer 251 may be disposed on the link area LKA and the bending area BDA of the substrate 201.

In the bending area BDA of the substrate 201, the first buffer layer 205, the first insulating structure 213, and the second insulating structure 219 may not be disposed, which are made of inorganic insulating material prone to crack formation. For example, in the bending area BDA of the substrate 201, the first planarization layer 251 may be disposed, which includes an organic insulating material. The first planarization layer 251 may be disposed to be in direct contact with the second base layer 203 of the substrate 201 on the bending area BDA. Since the first buffer layer 205, the first insulating structure 213, and the second insulating structure 219 of the substrate 201 are disposed within the link area LKA, the end portions of these layers may define a boundary between the link area LKA and the bending area BDA. For example, the end portion of the first buffer layer 205, which is disposed at the bottommost of the insulating layer-stacking structure, may define the boundary between the bending area BDA and the link area LKA.

On the first planarization layer 251, the connection wiring CL may be disposed. The connection wiring CL may extend to the pad area PDA through the link area LKA and the bending area BDA. The connection wiring CL may be formed from the same material as, and in the same process as, the pixel contact electrode 255 of the display area AA. In one example, the connection wiring CL may have a multilayer structure of titanium/aluminum/titanium (Ti/Al/Ti).

The connection wiring CL may penetrate the first planarization layer 251 in the first contact area CTA1 to be electrically connected with the link contact electrode LCT. Thereby, the connection wiring CL may be electrically connected with the first signal link wiring SL1 through the link contact electrode LCT. In one example, the link contact electrode LCT may be disposed for each first contact area CTA1, and neighboring link contact electrodes LCT may be insulated from each other.

On the connection wiring CL, the second planarization layer 252 may be disposed. The second planarization layer 252 may be disposed on the link area LKA and the bending area BDA, while covering the connection wiring CL. The second planarization layer 252 may planarize a step difference caused by the circuit element in the lower portion.

On the second planarization layer 252 of the link area LKA and the bending area BDA, the organic insulating structure 266 may be disposed. The organic insulating structure 266 may be formed from the same material as, and in the same process as, the bank 262 and the spacer 264 of the display area AA.

Thereby, on the substrate 201 of the bending area BDA, the first planarization layer 251, the second planarization layer 252, and the organic insulating structure 266 may be disposed, each including an organic insulating material.

Referring to FIGS. 1, 6, and 7, between the first planarization layer 251 and the second planarization layer 252, the plurality of connection wirings CL may be disposed. The plurality of connection wirings CL may include odd-numbered wirings CL_n and even-numbered wirings CL_n+1 n is a natural number.

The plurality of odd-numbered wirings CL_n and the plurality of even-numbered wirings CL_n+1 may have a linear shape stretching on the bending area BDA. The plurality of odd-numbered wirings CL_n and the plurality of even-numbered wirings CL_n+1 may be disposed in the same layer. Thereby, referring to FIG. 4, a signal provided from the control circuit chip of the printed circuit board may be transmitted from the second signal link wiring SL2, through the second contact area CTA2, by way of one connection wirings CL of the plurality of connection wirings CL arranged in the same layer and spaced apart from each other, through the first contact area CTA1, and to the first signal link wiring SL1, and then be supplied to the display area AA.

Since the bending area BDA is exposed at the lower end of the display panel 200, the plurality of connection wirings CL disposed on the bending area BDA may be vulnerable to external damage. For example, as shown in FIG. 7, the bending area BDA may be bent so that the pad area PDA may be hidden under the display area AA. As the bending area BDA is bent, stress S may be applied to materials disposed in the upper side of the connection wiring CL in the bending area BDA, such as the second planarization layer 252 and the organic insulating structure 266. The material disposed in the upper side of the connection wiring CL, to which the stress S is applied, may undergo the formation of cracks CR in local areas due to its contraction or expansion. The cracks CR formed in the material disposed in the upper side of the connection wiring CL may propagate to damage the connection wiring CL.

Alternatively, a local area of the bending area BDA may undergo the occurrence of a physical external force, thereby being pressed or clamped. Thereby, cracks may be formed in the connection wiring CL disposed in the area of the bending area BDA, to which the physical external force is applied. The crack propagation may proceed in a vertical direction of the connection wiring CL, so that a defect such as the disconnection of the connection wiring CL may occur.

Referring back to FIGS. 4 and 6, a signal provided from the control circuit chip of the printed circuit board may be transmitted from the second signal link wiring SL2, through the second contact area CTA2, by way of one connection wirings CL of the plurality of connection wirings CL arranged in the same layer and spaced apart from each other, through the first contact area CTA1, and to the first signal link wiring SL1, and then be supplied to the display area AA. Accordingly, when damage occurs in a local area of the bending area BDA and a crack occurs in one connection wirings CL of the plurality of connection wirings CL, the signal provided through this connection wiring CL may fail to reach the display area AA, thereby causing a defect such as non-operation in the display area AA. For example, when a crack occurs in an area including the 98th connection wiring CL_n+1, which is an even-numbered wiring among the plurality of connection wirings CL, and the 98th connection wiring CL_n+1 is disconnected, a signal provided to the display area AA through the 98th connection wiring CL_n+1 may not be provided. As a result, a defect may occur, in which the operation of the display apparatus is not performed, such as a pixel not lighting up in the display area AA.

To overcome this, another embodiment of the invention may include a configuration enabling continuous operation in the display area, even when damage occurs in a local area of the bending area BDA.

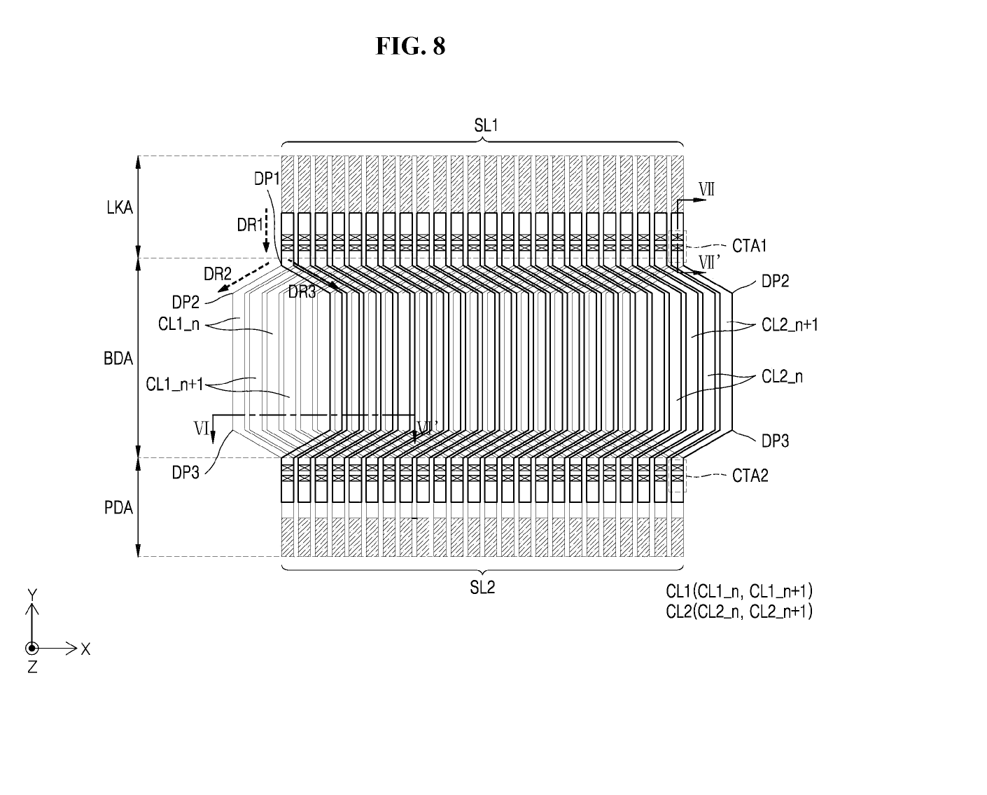

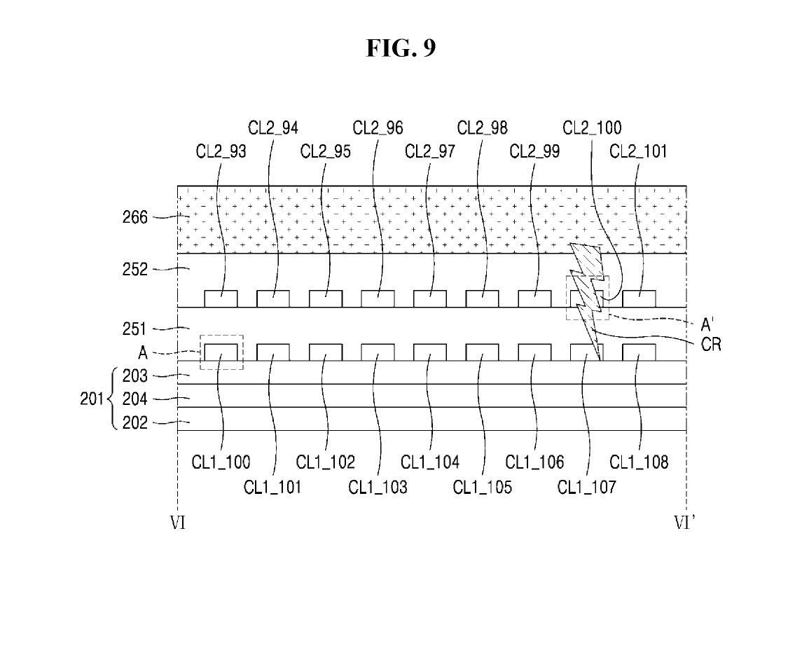

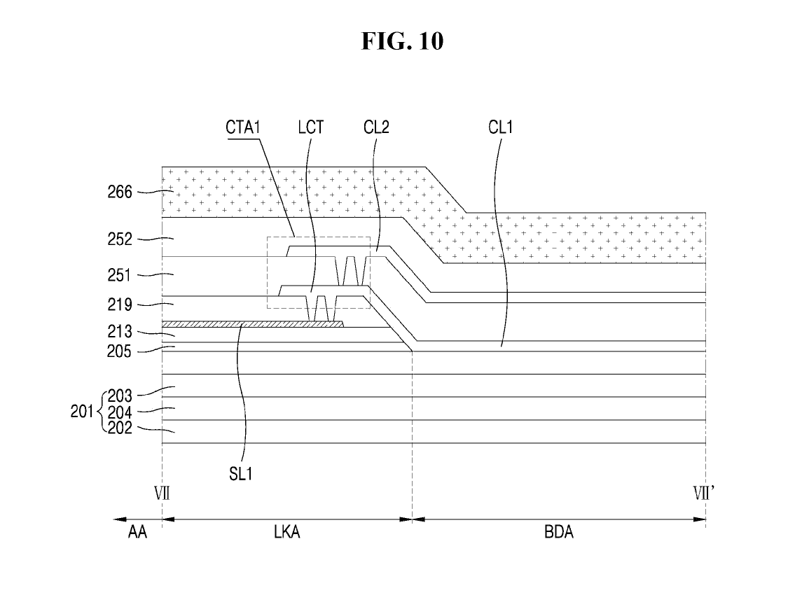

FIGS. 8 to 10 are illustrated according to another embodiment of the invention. FIG. 8 is a plan view showing an enlarged view of area III of FIG. 2. FIG. 9 is a cross-sectional view taken along line VI-VI’ in FIG. 8. FIG. 10 is a cross-sectional view taken along line VII-VII’ in FIG. 8. FIGS. 9 and 10 illustrate the organic insulating structure 266 (having the bank 262 and the spacer 264 shown in FIG. 3) stacked in the up and down direction, for convenience of explanation, while omitting the encapsulation part 270 and the touch sensor part 287, and the like which are disposed in the upper side of the organic insulating structure 266.

Referring to FIGS. 8 to 10, on the link area LKA, a plurality of first signal link wirings SL1 may be disposed, which transmit signals to the display area AA. For example, the plurality of first signal link wirings SL1 may include a plurality of data link wirings. Each of the plurality of first signal link wirings SL1 may be electrically connected to a second signal link wiring SL2 through a plurality of connection wirings CL1, CL2.

Each first signal link wiring SL1 may extend in the vertical direction Y in the link area LKA. Adjacent first signal link wirings SL1 may be arranged to be spaced apart from each other in the horizontal direction X. The horizontal direction X may refer to the lateral direction of the display panel, and the vertical direction Y may refer to the longitudinal direction of the display panel.

The plurality of connection wirings CL1, CL2 may extend from the link area LKA to the pad area PDA through the bending area BDA. The plurality of connection wirings CL1, CL2 may include a plurality of first connection wirings CL1 and a plurality of second connection wirings CL2. The plurality of first connection wirings CL1 and the plurality of second connection wirings CL2 may be disposed in different layers.

One end portions of the plurality of connection wirings CL1, CL2 may overlap with a first contact area CTA1 of the link area LKA, and the other end portions may overlap with a second contact area CTA2 of the pad area PDA.

The portions of the first connection wiring CL1 and the second connection wiring CL2, which are disposed in the link area LKA, may be disposed to overlap with each other in the up and down direction in the first contact area CTA1 along the first direction DR1, which is the vertical direction Y.

In the bending area BDA, the first connection wiring CL1 and the second connection wiring CL2 may be disposed along different directions. For example, each of the first connection wiring CL1 and the second connection wiring CL2 may include at least one deflection point in the bending area BDA. For example, the first connection wiring CL1 and the second connection wiring CL2 may include a first deflection point DP1, a second deflection point DP2, and a third deflection point DP3. The first deflection point DP1 may be located in the bending area BDA to be adjacent to the link area LKA, and the third deflection point DP3 may be located in the bending area BDA to be adjacent to the pad area PDA. The second deflection point DP2 may be located between the first deflection point DP1 and the third deflection point DP3.

The first connection wiring CL1 may be disposed along a second direction DR2, which is different from the first direction DR1, at the first deflection point DP1, and may be disposed along a third direction DR3, which is different from the second direction DR2, at the third deflection point DP3. And at the second deflection point DP2, it may be disposed along the same direction as the first direction DR1. For example, the second direction DR2 may be a diagonal direction toward the lower left. The third direction DR3 may be a diagonal direction toward the lower right.

The other end portion of the first connection wiring CL1, which extends toward the pad area PDA from the third deflection point DP3, may be disposed to overlap with the second connection wiring CL2 in the up and down direction along the first direction DR1, which is the vertical direction Y, at the second contact area CTA2 on the pad area PDA.

The second connection wiring CL2 may be disposed along a direction different from that of the first connection wiring CL1 at the first deflection point DP1 and the third deflection point DP3. For example, the second connection wiring CL2 may be disposed along the third direction DR3, which is different from the first direction DR1 and the second direction DR2, at the first deflection point DP1. In this way, it is possible to avoid that the first connection wiring CL1 and the second connection wiring CL2, to which one signal is supplied, overlap with each other in the up and down direction in the bending area BDA.

Also, the second connection wiring CL2 may be disposed along the second direction DR2, which is different from the first direction DR1 and the third direction DR3, at the third deflection point DP3. And the second connection wiring CL2 may be disposed along the same direction as the first direction DR1 at the second deflection point DP2. For example, the second direction DR2 may be a diagonal direction toward the lower left. The third direction DR3 may be a diagonal direction toward the lower right.

The other end portion of the second connection wiring CL2, which is disposed toward the pad area PDA from the third deflection point DP3, may be disposed to overlap with the first connection wiring CL1 in the up and down direction along the first direction DR1, which is the vertical direction Y, at the second contact area CTA2 on the pad area PDA.

The other end portions of the plurality of connection wirings CL1, CL2, which are opposite to one end portions thereof and extend to the pad area PDA through the bending area BDA, may overlap with the second contact area CTA2 of the pad area PDA. One end portions of the plurality of connection wirings CL1, CL2 may be electrically connected with the first signal link wiring SL1 in the first contact area CTA1, and the other end portions thereof may be electrically connected with the second signal link wiring SL2 in the second contact area CTA2.

Referring to FIG. 8, in each of the plurality of connection wirings CL1, CL2, odd-numbered wirings and even-numbered wirings may be alternately disposed. For example, the first connection wiring CL1 may include a plurality of first-first connection wirings CL1_n, which are odd-numbered wirings, and a plurality of first-second connection wirings CL1_n+1, which are even-numbered wirings (where n is a natural number). The plurality of first-first connection wirings CL1_n and the plurality of first-second connection wirings CL1_n+1 may be disposed in the same layer. This will be described in detail below with reference to FIG. 9.

For example, the second connection wiring CL2 may include a plurality of second-first connection wirings CL2_n, which are odd-numbered wirings, and a plurality of second-second connection wirings CL2_n+1, which are even-numbered wirings (where n is a natural number). The plurality of second-first connection wirings CL2_n and the plurality of second-second connection wirings CL2_n+1 may be disposed in the same layer. This will be described in detail below with reference to FIG. 9.

Referring to FIGS. 9 and 10, on the link area LKA of the substrate 201, the first buffer layer 205 may be disposed. On the first buffer layer 205, the first insulating structure 213 including an inorganic insulating material may be disposed.

On the first insulating structure 213, the first signal link wiring SL1 may be disposed. For example, the first signal link wiring SL1 may be a data link line, although it is not limited thereto. On the first signal link wiring SL1, the second insulating structure 219 including an inorganic insulating material may be disposed. Since the first buffer layer 205, the first insulating structure 213, and the second insulating structure 219 of the substrate 201 are disposed within the link area LKA, the end portions of these layers may define a boundary between the link area LKA and the bending area BDA. For example, the end portion of the first buffer layer 205, which is disposed at the bottommost of the insulating layer-stacking structure, may define the boundary between the bending area BDA and the link area LKA. For example, the end portion of each of the first buffer layer 205, the first insulating structure 213, and the second insulating structure 219 may be formed in an inclined surface shape.

On the second insulating structure 219, the first connection wiring CL1 may be disposed. The first connection wiring CL1 may be formed from the same material as, and in the same process as, the second source electrode 245 and the second drain electrode 246 on the display area AA. The first connection wiring CL1 may be electrically connected with the first signal link wiring SL1. For example, a portion of the first connection wiring CL1 may penetrate the second insulating structure 219 to be electrically connected with the first signal link wiring SL1.

The first connection wiring CL1 may extend toward the bending area BDA. For example, the first connection wiring CL1 may be disposed along the inclined surfaces at the end portions of the second insulating structure 219, the first insulating structure 213, and the first buffer layer 205 to extend to the bending area BDA. The first connection wiring CL1, which has extended to the bending area BDA, may further extend to the pad area PDA.

In the bending area BDA of the substrate 201, the first buffer layer 205, the first insulating structure 213, and the second insulating structure 219 may not be disposed. Thereby, the first connection wiring CL1 may be disposed to be in direct contact with the second base layer 203 of the substrate 201.

On the first connection wiring CL1 of the link area LKA and the bending area BDA, the first planarization layer 251 may be disposed. On the first planarization layer 251, the second connection wiring CL2 may be disposed. The second connection wiring CL2 may extend to the pad area PDA through the link area LKA and the bending area BDA. The second connection wiring CL2 may be formed from the same material as, and in the same process as, the pixel contact electrode 255 of the display area AA. In one example, the second connection wiring CL2 may have a multilayer structure of titanium/aluminum/titanium (Ti/Al/Ti).

The second connection wiring CL2 may penetrate the first planarization layer 251 in the first contact area CTA1 of the link area LKA to be electrically connected with the first connection wiring CL1. Thereby, the second connection wiring CL2 may be electrically connected with the first signal link wiring SL1 through the first connection wiring CL1. In one example, the first connection wiring CL1 may be disposed for each first contact area CTA1, and neighboring first connection wirings CL1 may be insulated from each other.

On the first planarization layer 251 and the second connection wiring CL2, the second planarization layer 252 may be disposed. The second planarization layer 252 may be disposed on the link area LKA and the bending area BDA of the substrate 201, while covering the second connection wiring CL2. The second planarization layer 252 may planarize a step difference caused by the circuit element in the lower portion.

On the second planarization layer 252 of the link area LKA and the bending area BDA, the organic insulating structure 266 may be disposed. The organic insulating structure 266 may be formed from the same material as, and in the same process as, the bank 262 and the spacer 264 of the display area AA.

Thereby, on the substrate 201 of the bending area BDA, the first planarization layer 251, the second planarization layer 252, and the organic insulating structure 266 may be disposed, each including an organic insulating material.

Referring to FIGS. 8 and 9, in each of the plurality of connection wirings CL1, CL2, odd-numbered wirings and even-numbered wirings may be alternately disposed in the same layer. FIG. 9 shows, as an illustrative example for explanation, a configuration in which a plurality of first connection wirings CL1 are disposed on the second base layer 203 of the substrate 201. For example, the plurality of first connection wirings CL1 may include the 100th first connection wiring CL1_100, the 101st first connection wiring CL1_101, the 102nd first connection wiring CL1_102, the 103rd first connection wiring CL1_103, the 104th first connection wiring CL1_104, the 105th first connection wiring CL1_105, the 106th first connection wiring CL1_106, the 107th first connection wiring CL1_107, and the 108th first connection wiring CL1_108, which are alternately disposed.

On the 100th first connection wiring CL1_101 to 108th first connection wiring CL1_108, the first planarization layer 251 may be disposed.

On the first planarization layer 251, the plurality of second connection wirings CL2 may be disposed. For example, the plurality of second connection wirings CL2 may include the 93rd second connection wiring CL2_93, the 94th second connection wiring CL2_94, the 95th second connection wiring CL2_95, the 96th second connection wiring CL2_96, the 97th second connection wiring CL2_97, the 98th second connection wiring CL2_98, the 99th second connection wiring CL2_99, the 100th second connection wiring CL2_100, and the 101st second connection wiring CL2_101.

For example, the 100th second connection wiring CL2_100 may receive the same signal from the printed circuit board 104 (see FIG. 1) through the pad area PDA as that of the 100th first connection wiring CL1_100 disposed on the substrate 201 which is a layer different from that on which the 100th second connection wiring CL2_100 is disposed. For example, the 101st second connection wiring CL2_101 may receive the same signal as that of the 101st first connection wiring CL1_101 disposed on a different layer.

Each of the 93rd to the 108th first connection wirings CL1_93 to CL1_108 of the plurality of first connection wirings CL1 disposed in the lower side is disposed to be shifted along the second direction DR2 from its first deflection point DP1, and each of the 93rd to the 101st second connection wirings CL2_93 to CL2_101 of the plurality of second connection wirings CL2 disposed in the different layer, the upper side, and receiving the same signal is disposed to be shifted along the third direction DR3 different from the second direction DR2, thereby avoiding that the first connection wiring CL1 and second connection wiring CL2, which receive the same signal, do not overlap with each other in the up and down direction.

The odd-numbered first-first connection wiring CL1_n disposed in the lower side and the even-numbered second-second connection wiring CL2_n+1 disposed in the upper side may be disposed to overlap with each other in the up and down direction with the first planarization layer 251, an insulating layer, interposed therebetween. The second-second connection wiring CL2_n+1 may include the nth second-second connection wiring (where n is a natural number) among the plurality of second connection wirings CL2, and the first-first connection wiring CL1_n overlapping with the second-second connection wiring CL2_n+1 in the up and down direction may include the first-first connection wiring at the n+7th position, which is located to be spaced apart by at least seven lines from the second-second connection wiring CL2_n+1 among the plurality of second connection wirings CL2, which is located at the nth position where n is a natural number.

For example, the 100th first connection wiring CL1_100 may overlap with the 93rd second connection wiring CL2_93 in the up and down direction. Also, the 107th first connection wiring CL1_107 may overlap with the 100th second connection wiring CL2_100 in the up and down direction. Thereby, the 100th first connection wiring CL1_100 and the 100th second connection wiring CL2_100, which receive the same signal, may be disposed at positions spaced apart from each other on different layers without overlapping with each other in the up and down direction. For example, the 100th second connection wiring CL2_100 may be disposed at a position shifted to the right by at least seven lines from the 100th first connection wiring CL1_100.

Accordingly, even when a crack CR caused by external force occurs at position A’, which is located at 100th second connection wiring CL2_100, the 100th first connection wiring CL1_100 that receives the same signal is disposed at position A, which is located at a position shifted at least seven lines to the left from the 100th second connection wiring CL2_100. As such, the 100th first connection wiring CL1_ 100 may remain unaffected by the crack, and thus, the signal may be transmitted toward the display area AA through the 100th first connection wiring CL1_100, thereby enabling normal operation of the display apparatus.

Additionally, the crack CR formed in positions to the left of the 100th second connection wiring CL2_100 may remain unaffected by the crack. As a result, the signal may be transmitted toward the display area AA with the 100th second connection wiring CL2_100 in the up and down direction. However, even in this case, the 107th second connection wiring (not shown), which receives the same signal as that of the 107th first connection wiring CL1_107, may remain unaffected by the crack. As a result, the signal may be transmitted toward the display area AA through the 107th second connection wiring CL2_107, thereby enabling normal operation of the display apparatus.

Therefore, even if a crack is formed by external force in some of the connection wirings providing a signal to the display area, the signal or voltage for the operation of the display area may be stably provided, thereby improving product reliability. In this way, it is possible to decrease the proportion of display apparatuses having defects caused by the damage to the connection wirings, which may, in turn, contribute to the reduction of production energy that would be required to produce additional display apparatuses, thereby having the effect of abating greenhouse gas emissions.

According to an embodiment of the invention, by disposing the connection wirings at different spaced-apart positions on different layers in the bending area of the non-display area, a signal may be transmitted through another connection wiring disposed in a different layer. As such, even if a crack is formed by external force in some of the connection wirings that provide a signal to the display area, the signal or voltage for the operation of the display area may be stably provided, thereby improving product reliability.

According to embodiments of the invention, the proportion of the display apparatus having a defect due to damage in the connection wiring may be reduced, thereby contributing to the reduction of production energy, which would be required to produce additional display apparatuses, thereby having the effect of abating greenhouse gas emissions.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a substrate including a display area and a non-display area disposed outside the display area;
a link area, a bending area, and a pad area, which are located in the non-display area;
a plurality of first signal link wirings disposed in the link area;
a plurality of second signal link wirings disposed in the pad area; and
a plurality of connection wirings disposed in the bending area, each being electrically connected between one of the plurality of first signal link wirings and one of the plurality of second signal link wirings,
wherein the plurality of connection wirings include a first connection wiring and a second connection wiring disposed on different layers with an insulating layer interposed therebetween.

2. The display apparatus of claim 1, wherein each of the first signal link wirings disposed in the link area overlaps with the first connection wiring and the second connection wiring in an up and down direction.

3. The display apparatus of claim 1, wherein each of the second signal link wirings disposed in the pad area overlaps with the first connection wiring and the second connection wiring in an up and down direction.

4. The display apparatus of claim 1, wherein each of the first connection wiring and the second connection wiring includes at least one deflection point in the bending area, at which the first connection wiring and the second connection wiring are bent in different directions.

5. The display apparatus of claim 4, wherein the deflection point includes:
a first deflection point located in the bending area to be adjacent to the link area;
a third deflection point located in the bending area to be adjacent to the pad area; and
a second deflection point disposed between the first deflection point and the third deflection point.

6. The display apparatus of claim 5, wherein:
the first connection wiring is disposed:
in the link area along a first direction, which is a vertical direction of the display area;
at the first deflection point along a second direction different from the first direction; and
at the third deflection point along a third direction different from the second direction, and the second deflection point is in a same direction as the first direction;
the second direction is a diagonal direction toward a first lower lateral side; and
the third direction is a diagonal direction toward a second lower lateral side opposite the first lower lateral side.

7. The display apparatus of claim 5, wherein:
the second connection wiring is disposed:
in the link area along a first direction, which is a vertical direction of the display area;
at the first deflection point along a third direction different from the first direction; and
at the third deflection point along a second direction different from the third direction, and the second deflection point is in a same direction as the first direction;
the second direction is a diagonal direction toward a first lower lateral side, and
the third direction is a diagonal direction toward a second lower lateral side opposite the first lower lateral side.

8. The display apparatus of claim 1, wherein:
the plurality of first connection wirings include first-first connection wirings and first-second connection wirings, which are disposed alternately with each other; and
the plurality of second connection wirings include second-first connection wirings and second-second connection wirings, which are disposed alternately with each other.

9. The display apparatus of claim 8, wherein the first-first connection wirings and the second-first connection wirings are each odd-numbered wirings, and the first-second connection wirings and the second-second connection wirings each include even-numbered wirings.

10. The display apparatus of claim 9, wherein the first-first connection wirings disposed in a lower side of the insulating layer and the second-second connection wirings disposed in an upper side of the insulating layer are disposed to overlap with each other in an up and down direction with the insulating layer interposed therebetween.

11. The display apparatus of claim 9, wherein the first-second connection wiring disposed in a lower side of the insulating layer and the second-first connection wiring disposed in an upper side of the insulating layer may be disposed to overlap with each other in an up and down direction with the insulating layer interposed therebetween.

12. The display apparatus of claim 10, wherein the second-second connection wirings include an nth second-second connection wiring among a plurality of second connection wirings, and the first-first connection wirings overlapping with the second-second connection wirings in an up and down direction include an n+7^{th} first-first connection wiring, which is spaced apart by at least seven lines from the nth second-second connection wiring among a plurality of second connection wirings, where n is a natural number.

13. The display apparatus of claim 1, wherein the first connection wiring and the second connection wiring provide a same signal to the display area.

14. The display apparatus of claim 1, wherein the insulating layer includes an organic insulating layer.
